(19) United States
(12) Patent Application Publication
(10) Pub. No.: US 2007/0240092 A1
(43) Pub. Date: Oct. 11, 2007

(54) Methods of Fabricating Application Specific Integrated Circuit (ASIC) Devices that Include Both Pre-Existing and New Integrated Circuit Functionality and Related ASIC Devices

(75) Inventors: Yun-Tae Lee, Seoul (KR); Jong-Woo Park, Gyeonggi-do (KR); Seon-Wook Hwang, Gyeonggi-do (KR)

Correspondence Address: MYERS BIGEL SIBLEY & SAJOVEC, PO BOX 37428, RALEIGH, NC, 27627, US

(73) Assignee: Samsung Electronics., Ltd.

(21) Appl. No.: 11/692,987

(22) Filed: Mar. 29, 2007

(30) Foreign Application Priority Data
Apr. 11, 2006 (KR) 10-2006-0032745

(51) Int. Cl. G06F 17/50; H03K 19/00

(52) U.S. Cl. 716/17

(57) ABSTRACT

A method of fabricating a semiconductor integrated circuit, such as an ASIC, and a semiconductor integrated circuit using the same, are cost effective and allow lower non-recurring engineering compared with a platform ASIC by separately embodying a cell-based base block chip and a custom block chip of a gate array system and then combining both chips. When fabricating the semiconductor integrated circuit, formed by combining at least one standard function block with a newly-developed custom function block, the method of fabricating the semiconductor integrated circuit includes forming a base block chip that embodies the standard function block. Then, a custom block chip that embodies the custom function block is separately formed, and the base block chip is combined with the custom block chip.

### CROSS-REFERENCE TO RELATED PATENT APPLICATION

This application claims the benefit under 35 U.S.C. §119 of Korean Patent Application No. 10-2006-0032745, filed on Apr. 11, 2006, in the Korean Intellectual Property Office, the disclosure of which is incorporated herein in its entirety by reference as if set forth fully herein.

### FIELD OF THE INVENTION

The present invention relates to methods of fabricating semiconductor integrated circuits, and more particularly, to methods of fabricating application specific integrated circuit (ASIC) devices and related ASIC-devices.

### BACKGROUND

As semiconductor fabrication techniques have moved from sub-micron dimensions to nanometer dimensions, both the time and expense required to develop new semiconductor integrated circuit designs has increased dramatically. Semiconductor integrated circuits may be developed using, for example, either a gate array system or a cell-based (also referred to as “standard cell”) system. Under the gate array system, a plurality of logic gates are arrayed on a semiconductor chip, and metal wires such as conductive traces are formed that interconnect the logic gates such that the logic gates implement the desired functionality. In contrast, under the cell-based system, the ASIC is fabricated by forming a plurality of pre-existing circuit designs (standard cells) on the semiconductor substrate. Typically, the standard cells are registered in a “library” of pre-qualified circuit designs.

Gate array ASIC devices such as, for example, FPGA/PLD products, may typically be developed relatively quickly and with lower development costs as compared to cell-based ASIC devices. However, gate array ASIC devices tend to be expensive to manufacture and may have low performance and high power dissipation. For example, a gate array ASIC device may have only one third or less the performance of a comparable cell-based ASIC device, and may have six times or more the power dissipation. As such, gate array ASIC devices are typically only implemented in prototyping applications where the ASIC device is used to verify performance in an initial development period or in end products that have a very low unit volume that is insufficient to support the higher development costs (or longer development timelines) associated with the design of a cell-based ASIC device.

“Platform” ASIC devices are also known in the art. A platform ASIC device refers to an ASIC device that represents a compromise between a gate array ASIC device and a cell-based ASIC device. Platform ASIC devices are built mainly using standard cells (referred to hereinafter as “standardized function blocks”) that are typically developed and maintained by the manufacturer as cell-based core/intellectual property (IP). Additional functionality that must be included in the ASIC device in order to implement the desired functionality is then implemented as newly-developed custom blocks that may be formed using the gate array system. Both the standard cells and the gate array system custom blocks are implemented on a single semiconductor substrate.

The performance, power dissipation and fabrication cost of a platform ASIC device typically is better than the corresponding performance, power dissipation and fabrication cost of a gate array ASIC device, but not as good as a cell-based ASIC device. By way of example, a typical platform ASIC device may have about 80% of the performance of a cell-based ASIC device, 120% of the power dissipation, and may cost about twice as much to manufacture. Platform ASIC devices are often suitable for products with a mid-range number of expected units (e.g., 50,000 to 150,000 units).

### SUMMARY

Pursuant to embodiments of the present invention, methods of fabricating semiconductor integrated circuit devices are provided in which at least one standard function block is combined with a newly-developed custom function block. Pursuant to these methods, a base block chip that embodies the standard function block is formed. A custom block chip that embodies the custom function block is formed separately. Then, the base block chip is combined with the custom block chip.

The custom block chip may be formed in some embodiments by arraying a plurality of logic gates on a semiconductor substrate, and forming wires that functionally connect the logic gates to implement the custom function block. The base block chip may be formed by using standard cells registered in a cell library. The base block chip and the custom block chip may have a common interface standard for signal and data transmission.

Pursuant to further embodiments of the present invention, semiconductor integrated circuits are provided that include at least one standard function block and a newly developed custom function block. These semiconductor integrated circuits may include a cell-based base block chip that embodies the standardized function block, and a separate custom block chip of a gate array system that is functionally combined with the base block chip, and which embodies the custom function block.

Pursuant to still further embodiments of the present invention, methods of fabricating ASIC devices that include a cell-based ASIC region and a gate array ASIC region are provided. Pursuant to these methods, the cell-based ASIC region is formed on a first semiconductor substrate by forming one or more cell-based integrated circuits according to standard cell-based integrated circuit designs that are stored in a cell library. The gate array ASIC region is formed on a second semiconductor substrate. The gate array ASIC region is configured to perform a custom function, and is formed by arraying a plurality of logic gates on the second semiconductor substrate and a plurality of conductive paths that interconnect the plurality of logic gates so as to perform the custom function. The cell-based ASIC region and the gate array ASIC region are then interconnected to form the ASIC device. In some embodiments, the first and second semiconductor substrates may be stacked. Moreover, the cell-based ASIC region and the gate array ASIC region may be interconnected according to a standardized interface for signal and data transmission.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a conventional platform ASIC device;

FIG. 2 is a graph showing the correlation between production volume and cost of PLDs, platform ASIC devices and cell-based ASIC devices; and

FIG. 3 is a block diagram of an ASIC device according to embodiments of the present invention.

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element such as a layer, region or substrate is referred to as being “on” another element, it can be directly on the other element or intervening elements may also be present. In contrast, when an element is referred to as being “directly on” another element, there are no intervening elements present. Other words used to describe the relationship between elements should be interpreted in a like fashion (i.e., “connected” versus “directly connected”, “between” versus “directly between”, “adjacent” versus “directly adjacent”, etc.).

Embodiments of the invention are described herein with reference to a cross-section illustration that is a schematic illustration of an idealized embodiment of the invention. As such, the thickness of layers and regions and elements in the drawing may be exaggerated for clarity. Additionally, variations from the shapes of the illustrations as a result, for example, of manufacturing techniques and/or tolerances, are to be expected.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, operations, elements, and/or components, but do not preclude the presence or addition of one or more other features, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this disclosure and the relevant art and will not be interpreted in an idealized or overly formal sense unless expressly so defined herein.

Gate array systems may be used to quickly and easily design various types of integrated circuits by interconnecting an array of pre-formed logic gates with wires. The logic gates and the interconnection thereof are selected in order to implement the desired integrated circuit functionality. Examples of known gate array ASIC devices include Programmable Read Only Memory (PROM) devices, Programmable Logic Array (PLA) devices, Programmable Array Logic (PAL) devices, Simple Programmable Logic Devices (SPLD), Complex Programmable Logic Devices (CPLD) and Field Programmable Gate Array (FPGA) devices. Because gate array ASIC devices have a low packing density of cells per unit area and high manufacturing costs, gate array ASIC devices have primarily been used for applications that have low demand. In contrast, cell-based ASIC devices (i.e., large-sized semiconductor integrated circuits that are formed by combining pre-existing standard cells that are typically registered in a cell library) may provide much higher performance and lower development costs. However, cell-based ASIC devices typically have much higher development costs.

In a platform ASIC device, the standard function blocks are implemented using a cell-based system in order to take advantage of the improved performance and lower manufacturing costs that are typically associated with use of a cell-based system. On the other hand, newly-developed functions, i.e. custom function blocks, are implemented using a gate array. Thus, in al platform ASIC, both a cell-based ASIC region and a gate array region are separately formed on a single semiconductor substrate. Wires are provided that interconnect the gate array and/or for other functions to complete the fabrication of the integrated circuit (IC).

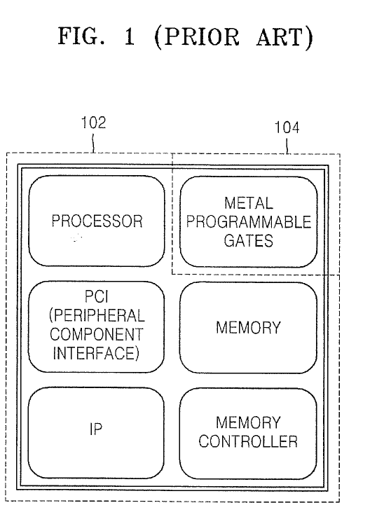

FIG. 1 is a block diagram of a conventional platform ASIC device. As shown in FIG. 1, a conventional platform ASIC device includes a cell-based ASIC region 102 and a gate array region 104. Both the cell-based ASIC region 102 and the gate array region 104 are formed on a semiconductor substrate such as, for example, a single-crystalline silicon substrate. In the cell-based ASIC region 102, standard function blocks such as a processor, a Peripheral Component Interface (PCI), an Intellectual Property (IP) module, a memory and a memory controller are formed. (The IP module is an intellectual property function module commonly usable in the ASIC design, which can greatly increase design efficiency.) Various other function blocks and/or elements such as, for example, an analog element, a passive element, etc. may also be formed in the cell-based ASIC region 102.

In the gate array region 104, a plurality of logic gates are arrayed on the semiconductor substrate, and metal wires are formed that interconnect the logic gates so as to perform the desired function.

Significant time and expense may be required in order to develop a cell-based ASIC function block. By incorporating already designed “standard” function blocks into an ASIC under development, large scale circuits can be developed at lower cost. Accordingly, a platform ASIC device such as the ASIC illustrated in FIG. 1 may be developed relatively quickly, (i.e., it has a fast Turn Around Time or “TAT”) and may have reduced Non-Recurring Engineering (NRE) costs.

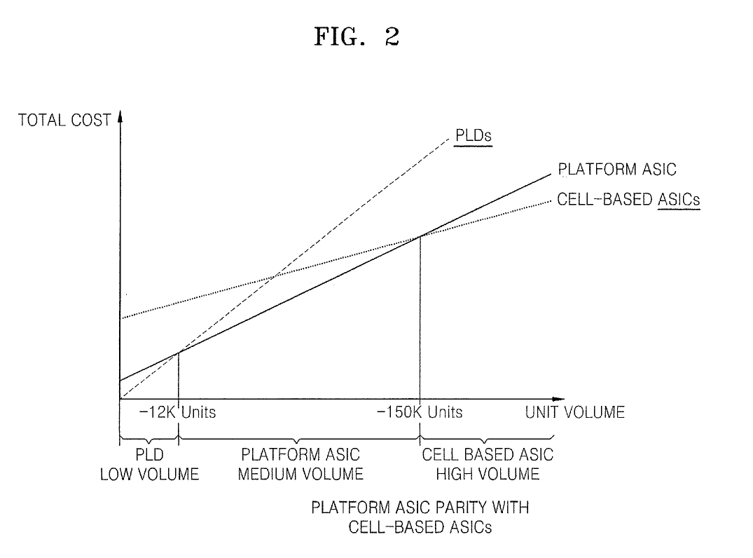

However, the total cost associated with a conventional platform ASIC device may exceed the total cost of a corresponding cell-based ASIC device, particularly when the total number of ASIC devices having a particular design that are to be produced is high (e.g., exceeds 150,000 units). Likewise, at very low volumes (e.g., less than 2,000 units), PLD devices may be preferable in terms of total cost, TAT and/or NRE. Accordingly, platform ASIC devices have primarily been used when the expected market for the ASIC is in a medium range (e.g., where the total number of units to be manufactured is in a range of about 2K˜150K or so). FIG. 2 is a graph showing the correlation between production volume and cost of PLDs, platform ASIC devices and cell-based ASIC devices.

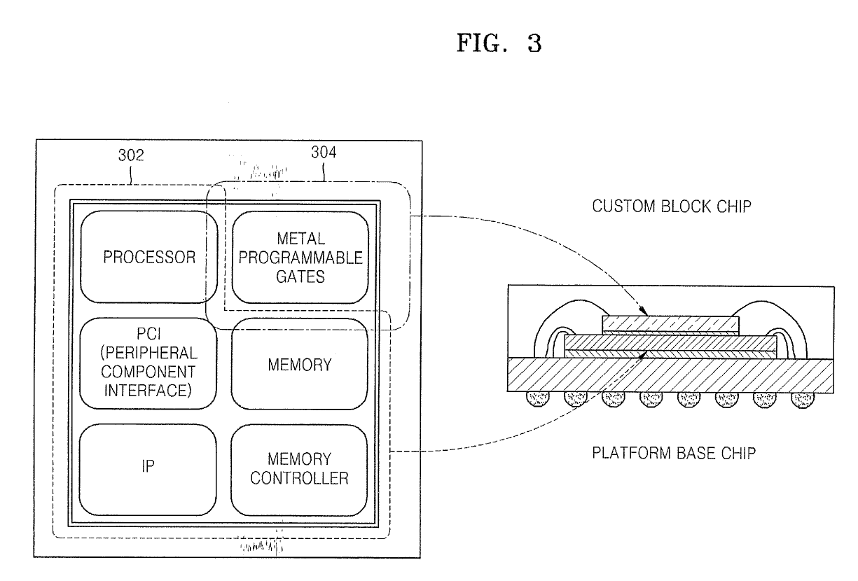

The left side of FIG. 3 is a block diagram of an ASIC device according to embodiments of the present invention. The right side of FIG. 3 is a schematic diagram illustrating the external appearance of such an ASIC. As shown in the block diagram (left side) of FIG. 3, ASIC devices according to embodiments of the present invention may include a base block chip 302 and a custom block chip 304. The base block chip 302 and the custom block chip 304 are composed of different chips. The base block chip 302 may implement standard function blocks, and the custom block chip 304 may implement the newly-developed functions, i.e. custom function blocks.

In ASIC devices according to embodiments of the present invention, the base block chip 302 is embodied by the cell-based ASIC, and the custom block chip 304 is embodied by the gate array ASIC. In other words, the cell-based base block chip 302 and the custom block chip 304 of the gate array system are prepared separately and then combined to fabricate the ASIC device.

In the base block chip 302 that is implemented as a cell-based ASIC, the standard function blocks such as a processor, a Peripheral Component Interface (PCI), an Intellectual Property (IP) module, a memory and a memory controller are formed. In some cases, an analog element, a passive element, etc. may be installed in the base block chip 302. The base block chip 302 may be designed as a General-Purpose Platform (GPP), an Application-Specific Design Platform, etc. and may be fabricated according to a development plan or a road map of a product group.

The custom block chip 304 may comprise a plurality of logic gates that are arrayed on a semiconductor substrate. Wires are formed that interconnect the logic gates in a manner that allows the custom block chip 304 to implement a desired functionality. The custom block chip 304 is then combined with the base block chip 302.

The custom block chip 304 may be formed as follows. A user designs a custom function block having a desired logic or function, and supplies the design to a manufacturer. The manufacturer fabricates a gate array ASIC device that implements the custom function block. Thereafter, the manufacturer combines the base block chip 302 and the custom block chip 304 to fabricate an ASIC device according to embodiments of the present invention.

ASIC devices according to embodiments of the present invention may have reduced costs in the custom block as compared to the conventional platform ASIC. Also, the base block chip 302 is already developed, and the custom block is newly developed. Thus, the NRE can be decreased as compared to platform ASIC devices. Furthermore, the development period of the ASIC devices according to embodiments of the present invention can be lower than for platform ASIC devices, and the development risk may be reduced.

Referring to the right side of FIG. 3, the base block chip 302 and the custom block chip 304 are electrically and functionally combined via externally formed terminals (not shown). In the embodiment of FIG. 3, the base block chip 302 and the custom block chip 304 are combined by stacking the custom block chip 304 on the base block chip 302. It will be appreciated that in other embodiments the base block chip 302 could be stacked on the custom block chip 304, or the blocks could be arranged in a side-by-side or some other relationship.

In some embodiments, the base block chip 302 and the custom block chip 304 may have a standardized interface such as, for example, PCI, PCI-express, UART, PCMCIA, 802.11, etc. interfaces.

While the present invention has been particularly shown and described with reference to exemplary embodiments thereof, it will be understood by those of ordinary skill in the art that various changes in form and detail may be made therein without departing from the spirit and scope of the present invention as defined by the following claims.

What is claimed is:

1. A method of fabricating a semiconductor integrated circuit by combining at least one standard function block with a newly-developed custom function block, comprising:
forming a base block chip that embodies the standard function block;
separately forming a custom block chip that embodies the custom function block; and
combining the base block chip with the custom block chip.

2. The method of claim 1, wherein forming the custom block chip comprises arraying a plurality of logic gates on a semiconductor substrate, and forming wires functionally connecting the logic gates to implement the custom block chip.

3. The method of claim 1, wherein forming the base block chip comprises using standard cells registered in a cell library to implement the base block chip.

4. The method of claim 1, wherein the base block chip and the custom block chip have a common interface standard for signal and data transmission.

5. A semiconductor integrated circuit having at least one standard function block and a newly developed custom function block, comprising:
a cell-based base block chip embodying the standardized function block; and
a separate custom block chip of a gate array system functionally combined with the base block chip, and embodying the custom function block.

6. The semiconductor integrated circuit of claim 5, wherein the base block chip and the custom block chip are combined by stacking.

7. The semiconductor integrated circuit of claim 5, wherein the base block chip and the custom block chip comprise a common interface for signal and data transmission.

8. A method of fabricating an ASIC device that includes a cell-based ASIC region and a gate array ASIC region, the method comprising:
forming the cell-based ASIC region on a first semiconductor substrate by forming one or more cell-based integrated circuits according to standard cell-based integrated circuit designs that are stored in a cell library;
forming the gate array ASIC region on a second semiconductor substrate, wherein the gate array ASIC region is configured to perform a custom function, and wherein the gate array ASIC region is formed by arraying a plurality of logic gates on the second semiconductor substrate and a plurality of conductive paths that interconnect the plurality of logic gates so as to perform the custom function; and
interconnecting the cell-based ASIC region and the gate array ASIC region to form the ASIC device.

9. The method of claim 8, further comprising stacking the first and second semiconductor substrates.

10. The method of claim 8, wherein the cell-based ASIC region and the gate array ASIC region are interconnected according to a standardized interface for signal and data transmission.

11. The method of claim 1, wherein forming a base block chip that embodies the standard function block comprises forming the base block chip that embodies the standard function block on the substrate while providing space on the base block chip for mounting the custom block chip thereon.
